(19) United States
(12) Patent Application Publication
(10) Pub. No.: US 2025/0385661 A1
(43) Pub. Date: Dec. 18, 2025

(54) FILTER DEVICE, MULTILAYER SUBSTRATE, AND COMMUNICATION APPARATUS

(71) Applicant: KYOCERA Corporation, Kyoto-shi, Kyoto (JP)

(72) Inventors: Hironori KII, Soraku-gun, Kyoto (JP); Junichiro TAKIKAWA, Kyotanabe-shi, Kyoto (JP)

(73) Assignee: KYOCERA Corporation, Kyoto-shi, Kyoto (JP)

(21) Appl. No.: 18/875,918

(22) PCT Filed: Jun. 9, 2023
(86) PCT No.: PCT/JP2023/021466

§ 371 Date: Dec. 17, 2024

(30) Foreign Application Priority Data
Jun. 21, 2022 (JP) 2022-099427

(51) Int. Cl. H03H 9/72; H03H 7/20; H03H 7/46

(52) U.S. Cl. CPC H03H 9/725; H03H 7/20; H03H 7/463

(57) ABSTRACT

A filter device includes a multilayer substrate, a chip mounted on the multilayer substrate, a first filter at least partially included in the chip, and a first hybrid coupler connected to the first filter. A part of the first hybrid coupler is included in the multilayer substrate, and another part of the first hybrid coupler is included in the chip.

### TECHNICAL FIELD

The present disclosure relates to filter devices including filters and hybrid couplers, multilayer substrates usable in the filter devices, and communication apparatuses including the filter devices.

### BACKGROUND OF INVENTION

A known filter device includes a combination of a filter and a hybrid coupler (e.g., Patent Literatures 1 and 2). A known hybrid coupler uses a lumped constant element (e.g., Patent Literatures 3 to 5). In Patent Literatures 3 to 5, an inductor, a capacitor, and a resonator are each mentioned as a lumped constant element included in a hybrid coupler. A hybrid coupler performs an intended operation (including distribution, phase adjustment, and/or combination of an input signal) at a predetermined operating frequency. Patent Literatures 3 to 5 each indicate the relationship between the operating frequency and an inductance value and/or a capacitance value of the lumped constant element in various configurations of the hybrid coupler. The contents of Patent Literatures 1 to 5 may be incorporated herein by reference.

### CITATION LIST

### Patent Literature

Patent Literature 1: PCT International Publication No. WO 2022/054896
Patent Literature 2: Japanese Unexamined Patent Application Publication No. 2022-041537
Patent Literature 3: Japanese Unexamined Patent Application Publication No. 8-335841
Patent Literature 4: Japanese Unexamined Patent Application Publication No. 2006-186960
Patent Literature 5: PCT International Publication No. WO 2019/163061

### SUMMARY

In an aspect of the present disclosure, a filter device includes a multilayer substrate, a chip, a first filter, and a first hybrid coupler. The chip is mounted on the multilayer substrate. The first filter is at least partially included in the chip. A part of the first hybrid coupler is included in the multilayer substrate and another part of the first hybrid coupler is included in the chip. The first hybrid coupler is connected to the first filter.

In an aspect of the present disclosure, a multilayer substrate includes a first surface, a pad, and a first circuit. The pad is located at the first surface and a chip is mountable on the pad. The first circuit includes a first hybrid coupler. The first circuit includes four inductors and four ports. The four inductors are series-connected to one another and electrically constitute a loop. The four ports are electrically positioned respectively among the four inductors. A first port of the four ports is connected to the pad. The first port and a reference potential section are unconnected when the chip is not mounted on the pad.

In an aspect of the present disclosure, a communication apparatus includes the aforementioned filter device, an antenna, and an integrated circuit element. The antenna is connected to the filter device. The integrated circuit element is connected to the antenna via the filter device.

### BRIEF DESCRIPTION OF THE DRAWINGS

FIG. 1 is a perspective view illustrating the configuration of a filter device according to an embodiment.

FIG. 2 is a schematic perspective view illustrating a part of an internal configuration of a multilayer substrate of the filter device in FIG. 1.

FIG. 3 is a circuit diagram illustrating the configuration of a part of the filter device in FIG. 1.

FIG. 4 is a schematic plan view illustrating the configuration of an acoustic wave element included in the filter device in FIG. 1.

FIG. 5 is a schematic plan view illustrating the configuration of a chip included in the filter device in FIG. 1.

FIG. 6 is a circuit diagram illustrating the configuration of the filter device in FIG. 1.

FIG. 7 is a block diagram illustrating the configuration of a communication apparatus according to an embodiment.

### DESCRIPTION OF EMBODIMENTS

Embodiments according to the present disclosure will be described below with reference to the drawings. The drawings used in the following description are schematic. Therefore, for example, dimensional ratios and the like in the drawings do not necessarily match those in reality. Moreover, the dimensional ratios and the like may sometimes not match between the drawings. Specific shapes, dimensions, and/or the like may sometimes be exaggerated, and details may sometimes be omitted. However, it is not to be negated that the actual shapes and/or dimensions may be as illustrated in the drawings, or that the characteristics of the shapes and/or dimensions may be extracted from the drawings.

In the present disclosure, the expression “the phase of a signal is shifted” and the like may imply that the phase is advanced or retarded. However, for the sake of convenience, the term “shift” and the like as in the above expression imply only either one of the two commonly for various components, various signals, and the like, so long as an inconsistency and the like do not occur. For example, when the phase of a second signal is shifted by 90° relative to the phase of a first signal and the phase of a fourth signal is shifted by 90° relative to the phase of a third signal, the shift in the former and the shift in the latter imply that the phases are both advanced by 90°, or are both retarded by 90°.

### Main Points of Filter Device According to Embodiment

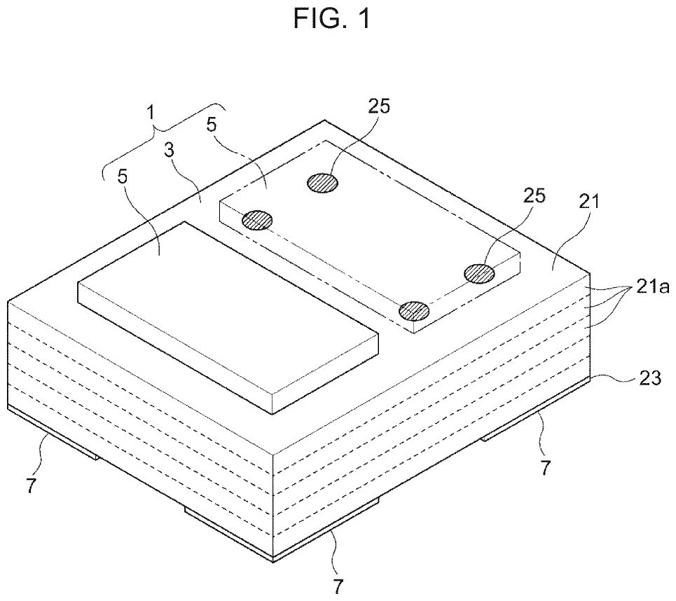

FIG. 1 is a perspective view illustrating an example of the configuration of a filter device 1 according to an embodiment. Although the filter device 1 is used with any direction thereof as an upward direction, the upper side in the plane of the drawing in FIG. 1 (i.e., a side where a chip 5 is positioned relative to a multilayer substrate 3) may sometimes be expressed as the upper side in the following description for the sake of convenience.

The filter device 1 includes a multilayer substrate 3 and at least one chip 5 (two in the illustrated example) mounted on the multilayer substrate 3. The multilayer substrate 3 includes multiple external terminals 7. For example, the filter device 1 filters a signal input from any one of the multiple external terminals 7 and outputs the signal from another one of the multiple external terminals 7.

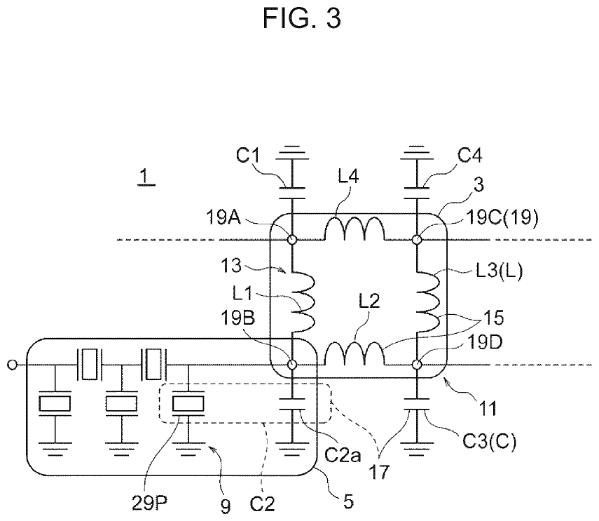

FIG. 3 is a circuit diagram illustrating an example of the configuration of a part of the filter device 1.

As mentioned above, the filter device 1 includes the multilayer substrate 3 and the chip 5. From a different viewpoint, the filter device 1 includes a first filter 9 and a hybrid unit 11 connected to the first filter 9.

For example, the first filter 9 directly contributes to the aforementioned filtering function of the filter device 1. More specifically, for example, the first filter 9 is a bandpass filter that attenuates a signal included in an input signal and having a frequency outside a predetermined passband, so as to output a signal having a frequency within the passband. The hybrid unit 11 contributes to, for example, reduction of nonlinear distortion occurring in the first filter 9, as will be described in detail later.

The hybrid unit 11 is, for example, a lumped-constant 90° hybrid coupler. For example, the hybrid unit 11 includes four series elements 15 (L1 to L4) series-connected to one another and constituting a loop 13, and also includes four parallel elements 17 (C1 to C4) respectively connected to sections (four ports 19A to 19D) among the four series elements 15. The four parallel elements 17 are connected to ground (i.e., connected to a reference potential section). In the illustrated example, the four series elements 15 are inductors L1 to L4, respectively, and the four parallel elements 17 are four capacitors C1 to C4, respectively. In the following description, the inductors L1 to L4 may sometimes be simply referred to as “inductors L” without being distinguished from one another. The capacitors C1 to C4 may sometimes be simply referred to as “capacitors C” without being distinguished from one another. The ports 19A to 19D may sometimes be simply referred to as “ports 19” without being distinguished from one another.

The first filter 9 is constituted by the at least one chip 5. In other words, the first filter 9 is included in the at least one chip 5. With regard to the hybrid unit 11, one part thereof is constituted by the multilayer substrate 3 (i.e., is included in the multilayer substrate 3), while another part is constituted by the at least one chip 5 (i.e., is included in the at least one chip 5). In the illustrated example, the loop 13 (i.e., the series elements 15) is included in the multilayer substrate 3, and one of the parallel elements 17 (more specifically, the capacitor C2) is included in the chip 5.

For example, this configuration exhibits the following advantages.

The hybrid unit 11 does not exhibit an intended function on signals in all frequency bands, but exhibits an intended function on a signal with a specific operating frequency (or in a frequency band including the operating frequency; the same applies hereinafter, unless otherwise noted). The operating frequency of the hybrid unit 11 is defined in accordance with the capacitance and the inductance of each of the series elements 15 and the parallel elements 17.

The hybrid unit 11 is connected to the first filter 9 and, for example, is expected to exhibit an intended function on a signal passing through the first filter 9. Thus, the operating frequency of the hybrid unit 11 is set in accordance with the passband of the first filter 9 connected to the hybrid unit 11.

Accordingly, supposing that the hybrid unit 11 is entirely provided in the multilayer substrate 3, the multilayer substrate 3 is to have different configurations for the first filter 9 having different passbands (i.e., the chip 5 from a different viewpoint). In other words, the filter device 1 having different passbands is to include different multilayer substrates 3.

In contrast, in the filter device 1 according to the embodiment, a part of the hybrid unit 11 is provided in the chip 5. By adjusting the inductance and/or the capacitance (i.e., the capacitance in the illustrated example) of the aforementioned part, the operating frequency of the hybrid unit 11 can correspond with the passband of the first filter 9. Therefore, the multilayer substrate 3 can have a common configuration for the first filter 9 (chip 5) having different passbands. This results in enhanced productivity of the multilayer substrate 3 (i.e., the filter device 1 from a different viewpoint).

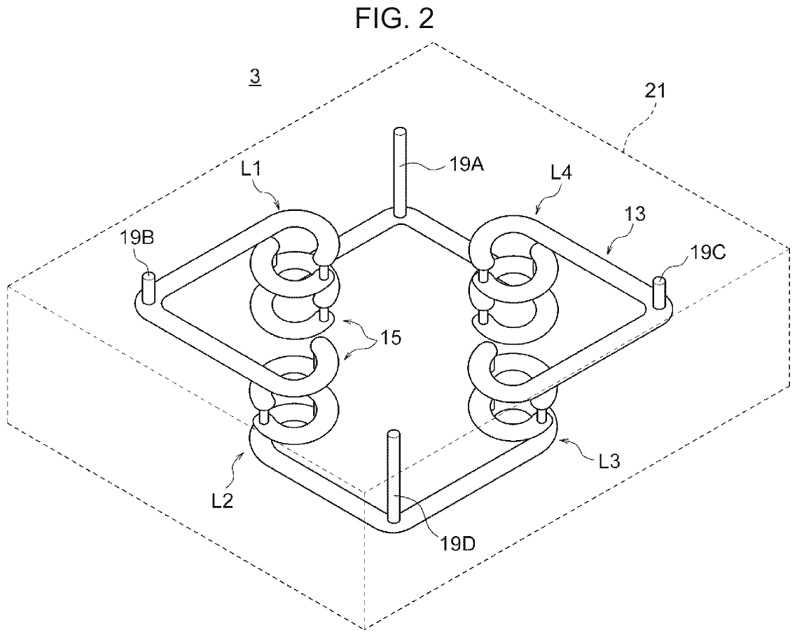

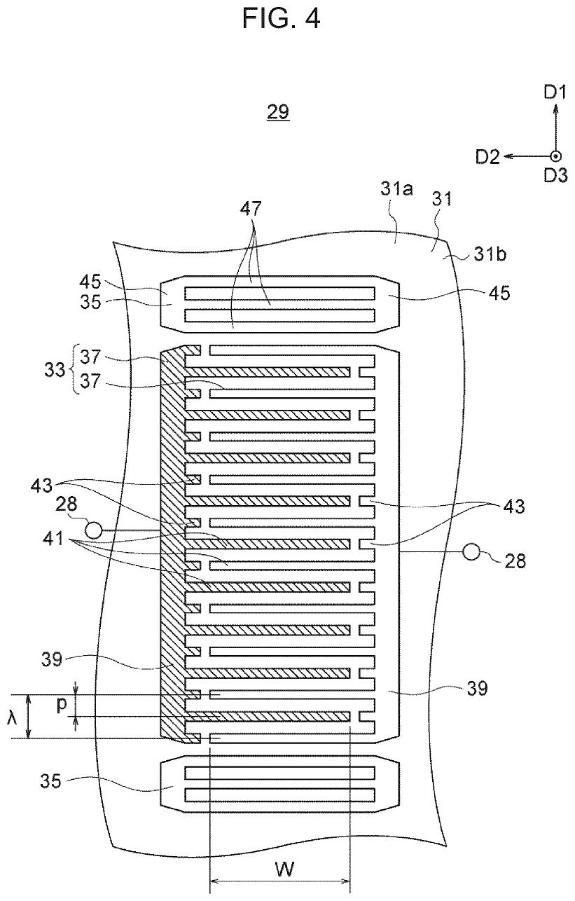

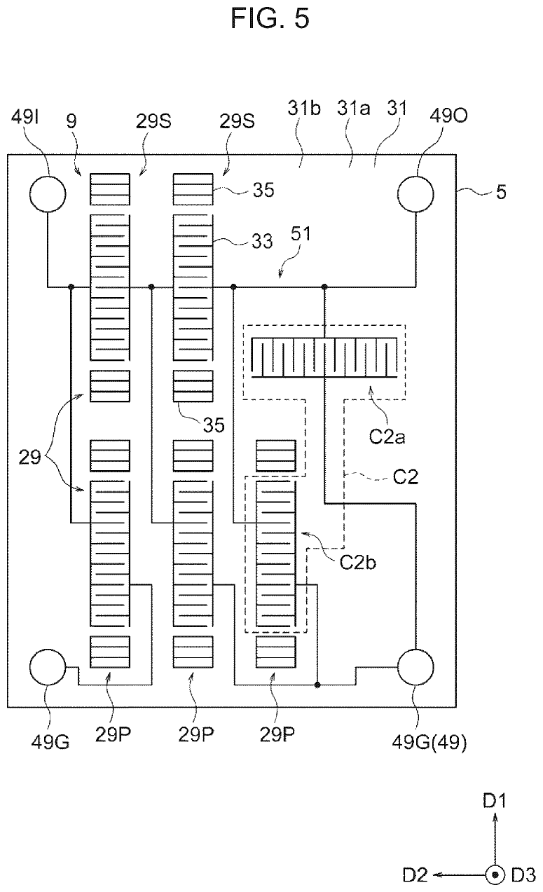

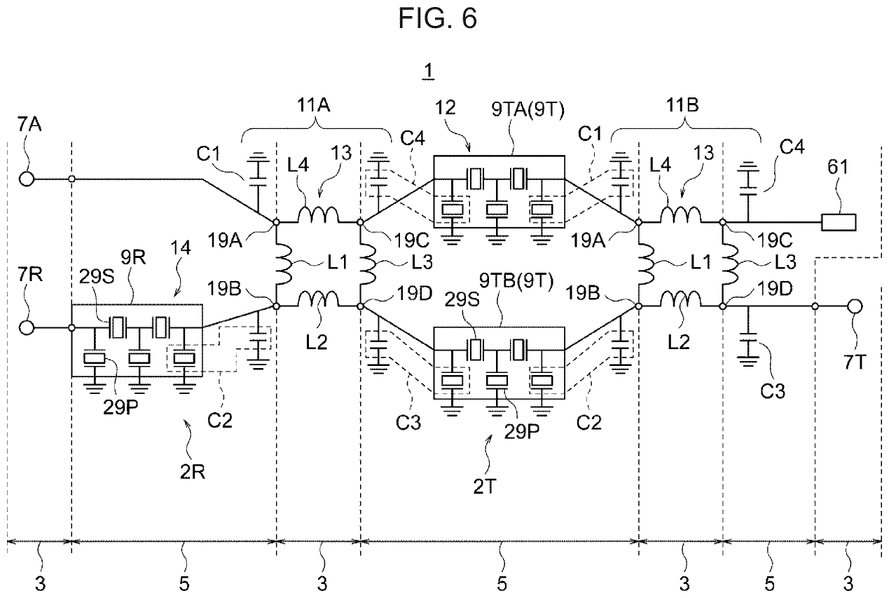

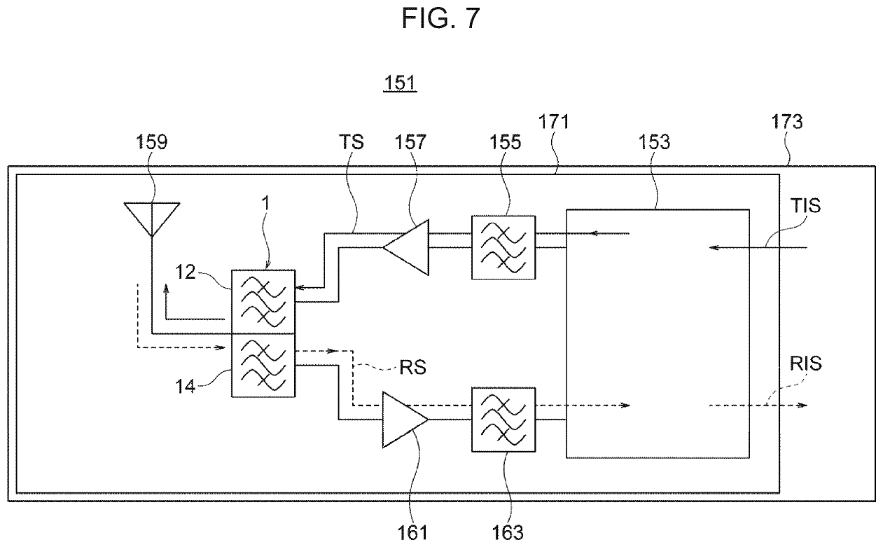

The main points of the filter device 1 according to the embodiment have been described above. The filter device 1 will be generally described below in the following order.
1. Outline of Filter Device 1 (FIG. 1)
2. Multilayer Substrate 3 (Excluding Hybrid Unit 11)
3. Basic Points of Hybrid Unit 11 (FIG. 3)
3.1. Operation of Hybrid Unit 11
3.2. Circuit Configuration of Hybrid Unit 11
4. First Filter 9
4.1. Outline of First Filter 9
4.2. Example of Acoustic Wave Resonator (FIG. 4)
4.3. Ladder Filter (FIG. 5)
5. Chip 5
6. Part of Hybrid Unit 11 Located in Multilayer Substrate 3 (FIG. 2)
7. Part of Hybrid Unit 11 Located in Chip 5 (FIG. 3 and FIG. 5)
8. Example of Circuit Configuration of Entire Filter Device 1 (FIG. 6)
8.1. Basic Points of Circuit Configuration
8.2. Distribution of Filter Device 1 to Multilayer Substrate 3 and Chip 5
9. Communication Apparatus Including Filter Device 1 (FIG. 7)
10. Overview of Embodiment

### 1. Outline of Filter Device 1

The filter device 1 illustrated in FIG. 1 is, for example, a surface-mounted-chip-type electronic component. For example, the filter device 1 includes, as the aforementioned multiple external terminals 7, layered conductors located at the lower surface of the filter device 1. While facing a pad located on the upper surface of a circuit board (not illustrated), the multiple external terminals 7 are bonded to the aforementioned pad by using a conductive bonding material interposed therebetween. The conductive bonding material is a bump from a different viewpoint, and the material thereof is, for example, solder (the same applies hereinafter). The number, position, shape, size, and the like of the multiple external terminals 7 may be appropriately set in accordance with the function and the like of the filter device 1.

As mentioned above, the filter device 1 includes the multilayer substrate 3 and the at least one chip 5. The number, position, shape, size, and the like of the chip 5 may be appropriately set in accordance with the function and the like required in the filter device 1. The filter device 1 may include a component other than those illustrated. An example of such a component includes a sealant or cover covering the upper surface of the multilayer substrate 3 from above the chip 5. The filter device 1 as a chip-type electronic component may have any general shape and size. For example, the filter device 1 entirely has a substantially thin rectangular-parallelepiped shape.

The filter device 1 may have various structures other than that in the illustrated example so long as the filter device 1 includes the multilayer substrate 3 and the chip 5 (although the illustrated configuration may be assumed for the sake of convenience in the description of the embodiment). The filter device 1 may be a chip-type electronic component having only the function of a filter, or may be combined indivisibly with an element having a function different from a filter.

For example, the filter device 1 does not need to be a chip-type electronic component. More specifically, for example, although not specifically illustrated, in a substantially substrate-like module including a circuit board, an IC (integrated circuit) mounted on or contained in the circuit board, an antenna mounted on or contained in the circuit board, and the filter device 1, the multilayer substrate 3 may be the aforementioned circuit board.

For example, the filter device 1 may include a container-like package containing the multilayer substrate 3 and the chip 5. An external terminal provided in the package and a terminal (external terminal 7) of the multilayer substrate 3 may be electrically connected to each other.

For example, the filter device 1 as a chip-type electronic component including the external terminals 7 at the multilayer substrate 3 is not limited to including the layered external terminals 7 at the lower surface. For example, the layered external terminals 7 located at the upper surface may be connected to the circuit board (not illustrated) by using a bonding wire. For example, pin-like external terminals 7 may be bonded to the multilayer substrate 3.

### 2. Multilayered Substrate

The basic structure and material of the multilayer substrate 3 (circuit board) (i.e., the configuration excluding the specific pattern and size of conductors for constituting the filter device 1) may be the same as and/or similar to the structure and material of various known printed boards. For example, the multilayer substrate 3 may be an LTCC (low temperature co-fired ceramic) substrate, an HTCC (high temperature co-fired ceramic) substrate, an IPD (integrated passive device) substrate, or an organic substrate.

An example of the LTCC substrate can be baked at a low temperature (e.g., about 900° C.) by adding alumina to a glass-based material. In the LTCC substrate, a conductive material used may be, for example, Cu or Ag. As the HTCC substrate, a ceramic material having alumina or aluminum nitride as a main component is used. In the HTCC substrate, a conductive material used may be, for example, tungsten or molybdenum. An example of the IPD substrate has a passive element in a Si substrate. The organic substrate has a layered pre-preg having resin impregnated in a base material made of glass and/or the like.

The multilayer substrate 3 includes an insulative base 21 and a conductor 23 located inside and/or on the surface of the base 21. As is apparent from the previous paragraph, the base 21 and the conductor 23 may each be made of any material. The base 21 may include, for example, multiple stacked insulative layers 21a. The base 21 may have any shape and size. In the illustrated example, the base 21 has a thin rectangular-parallelepiped shape. The conductor 23 includes, for example, a conductor layer (without a reference sign) located on the upper surface or lower surface (main surface) of the insulative layers 21a, and a via conductor (see FIG. 2, without a reference sign) extending through the insulative layers 21a. The number of conductor layers and via conductors, the positions thereof, the shapes thereof, the sizes thereof, and the like may be appropriately set in accordance with the function and the like required in the multilayer substrate 3.

As an example of the conductor 23 (conductor layer), FIG. 1 illustrates the aforementioned multiple external terminals 7 and multiple pads 25 for mounting the chip 5 to the multilayer substrate 3. As is apparent from an example (FIG. 6) of the circuit configuration of the entire filter device 1 to be described below, each external terminal 7 and each pad 25 are connected to each other via, for example, a wiring line and/or an element (not illustrated in FIG. 1) included in the multilayer substrate 3. Accordingly, the first filter 9 included in the chip 5 can filter a signal input from any of the external terminals 7 and output the signal to another external terminal 7.

For example, the multiple pads 25 overlap the upper surface of the base 21. For example, while facing layered external terminals (not illustrated) located at the lower surface of the chip 5, the multiple pads 25 are bonded to the layered external terminals via a conductive bonding material (not illustrated) interposed therebetween. Accordingly, the chip 5 is surface-mounted on the multilayer substrate 3. The number, position, shape, size, and the like of the multiple pads 25 may be appropriately set in accordance with the number of one or more chips 5 and the number, position, shape, size, and the like of the external terminals of each chip 5. Unlike the illustrated example, each pad 25 may be electrically connected to an external terminal provided at the upper surface of the chip 5 by using a bonding wire.

### 3. Basic Points of Hybrid Unit

### (3.1. Operation of Hybrid Unit)

As mentioned above, the hybrid unit 11 illustrated in FIG. 3 is a 90° hybrid coupler including the four ports 19. As is known, a 90° hybrid coupler has the functions of a distributor, a combiner, and a 90° phase shifter. The details are as follows. A signal in the following description has a frequency at which an intended function is exhibited in the hybrid unit 11, unless otherwise noted.

The ports 19A and 19B at the left side of the drawing are respectively electrically conductive with the ports 19C and 19D at the right side of the drawing. The expression “electrically conductive” implies that a signal is allowed to flow. Thus, for example, a signal input to the port 19A can be output from the ports 19C and 19D.

For the sake of convenience, the description of the embodiment may sometimes be based on the positional relationship among the ports 19A to 19D in the diagram illustrating the hybrid unit 11. Alternatively, the positional relationship among the four ports 19A to 19D in the diagram and the positional relationship among the four ports 19A to 19D in actuality do not need to match.

The signal input to the port 19A at the left side of the drawing is distributed to the ports 19C and 19D at the right side of the drawing. The distribution ratio in this case (i.e., the intensity ratio between two distributed signals) is 1:1. The intensity is, for example, voltage, current, and/or power. The two distributed signals are phase-shifted from each other by 90°.

The phase of the signal prior to the distribution (e.g., the signal input to the port 19A) and the phase of one of the two signals after the distribution (e.g., the signal output from the port 19C) may be the same. Unlike the above, the phase of the signal prior to the distribution and the phase of both of the two signals after the distribution may be different from each other. However, in the description of this embodiment, the phase of the signal prior to the distribution and the phase of one of the two signals after the distribution may sometimes be described as if they are the same for the sake of convenience. In detail, the phases of signals at ports at the same position in the up-down direction in the drawing (e.g., the ports 19A and 19C) may be described as if they are the same.

Although an example where the signal is input to the port 19A is described, the above operation is the same and/or similar when a signal is input to any of the other ports 19B to 19D. Specifically, a signal input to one of two ports located at one of the left and right sides of the drawing is distributed at a distribution ratio of 1:1, and is output from two ports located at the other one of the left and right sides of the drawing. In this case, the two distributed signals are phase-shifted from each other by 90°.

As mentioned above, the expression “phase-shifted” implies that the phase is shifted toward the advance side or the retard side commonly for various components, various signals, and the like for the sake of convenience. In the expression in the drawings, a signal output from a port (e.g., 19D) at a different position, in the up-down direction of the drawing, from a port (e.g., 19A) receiving the signal is assumed to be phase-shifted by 90° relative to a signal output from a port (e.g., 19C) at the same position, in the up-down direction of the drawing, as the port receiving the signal.

Because a 90° hybrid unit operates as described above, the relationship among the four ports of the hybrid unit 11 can be identified only from the description related to some of the ports. In the following description, for example, the port 19D is assumed as being a port to which a signal phase-shifted by 90° relative to the phase of a signal distributed from the port 19A to the port 19C is distributed from the port 19A. It is derived from this description that the port 19A and the remaining port 19B are located at the same side in the left-right direction of the drawing, the port 19C and the port 19D are located at the opposite side thereof, the port 19A and the port 19C are located at the same side in the up-down direction of the drawing, and the port 19B and the port 19D are located at the opposite side thereof. When the relationship among the four ports is described in accordance with the signal distributed from the port 19A as in the above, the hybrid unit 11 does not need to be provided in a configuration that receives a signal from the port 19A in actuality.

When the ports 19A and 19B at the left side of the drawing respectively receive signals, the signals are distributed as described above, and the distributed signals are combined with each other. For example, a signal input to the port 19A will be defined as a first signal, and a signal input to the port 19B will be defined as a second signal. Signals obtained as a result of distributing the first signal to the ports 19C and 19D will be defined as a third signal and a fourth signal. The fourth signal is phase-shifted by 90° relative to the third signal. Signals obtained as a result of distributing the second signal to the ports 19C and 19D will be defined as a fifth signal and a sixth signal. The fifth signal is phase-shifted by 90° relative to the sixth signal. In this case, a signal obtained as a result of combining the third signal and the fifth signal is output to the port 19C, and a signal obtained as a result of combining the fourth signal and the sixth signal is output to the port 19D. Although the above-described case relates to when the two ports 19A and 19B at the left side of the drawing receive signals, the same applies to when the two ports 19C and 19D at the right side of the drawing receive signals.

As mentioned above, for example, there may be a phase difference between the aforementioned first signal (input to the port 19A) and the third signal (distributed to the port 19C without being phase-shifted), and there may be a phase difference between the second signal (input to the port 19B) and the sixth signal (distributed to the port 19D without being phase-shifted). In this case, the aforementioned two phase differences are equal to each other. Two phase differences when the signals are oriented in opposite directions are also the same as the aforementioned two phase differences.

### (3.2. Circuit Configuration of Hybrid Unit)

A circuit configuration (i.e., a basic configuration excluding a specific shape, size, and the like of the conductor) of the hybrid unit 11 may be any of various configurations and may be, for example, a known configuration, so long as the above-described functions can be exhibited and one part (i.e., a part included in the multilayer substrate 3) and another part (i.e., a part included in the chip 5) where the operating frequency is adjustable are separable from each other.

In the illustrated example, as mentioned above, the hybrid unit 11 includes the four series elements 15 constituting the loop 13 and the four parallel elements 17 connecting the four ports 19 to ground. As another configuration, for example, the four series elements 15 each include two elements, and parallel elements 17 connecting parts between the aforementioned two elements to ground are provided in place of the parallel elements 17 connecting the ports to ground (e.g., FIG. 8 in Patent Literature 4 described above).

In the hybrid unit 11 including the four series elements 15 constituting the loop 13 and the four parallel elements 17 connecting the four ports 19 to ground, the series elements 15 and the parallel elements 17 may be various electronic elements (e.g., inductors, capacitors, and resonators). In the illustrated example, as mentioned above, the four series elements 15 are four inductors, and the four parallel elements 17 are four capacitors.

Examples of configurations other than that in the illustrated example are as follows. The four series elements 15 are four capacitors, and the four parallel elements 17 are four inductors. Two of the series elements 15 are two inductors, the remaining two series elements 15 connecting these two inductors are two capacitors, and the four parallel elements 17 are four capacitors. Two of the series elements 15 are two inductors, the remaining two series elements 15 connecting these two inductors are two parallel resonant circuits, and the four parallel elements 17 are four capacitors. The four series elements 15 are four parallel resonant circuits, and the four parallel elements 17 are four capacitors. The four series elements 15 are four inductors, and the four parallel elements 17 are four series resonant circuits.

The illustrated example and the various configurations indicated in the previous paragraph are disclosed in Patent Literatures 3 to 5 described above. The relationship between various parameter values of the series elements 15 and the parallel elements 17 (e.g., inductors and capacitors) and the operating frequency is known in the related art, or is described in Patent Literatures 3 to 5 described above. Therefore, the description about the overall relationship between the parameter values and the operating frequency in the various configurations will not be provided here.

In the illustrated example, the inductances of the inductors L1 and L3 are equal to one another. The inductances of the inductors L2 and L4 are equal to one another. The inductances of the inductors L1 and L3 and the inductances of the inductors L2 and L4 are normally different. The capacitances of the capacitors C1 to C4 are equal to one another. For example, increasing the capacitances of the capacitors C1 to C4 reduces the operating frequency of the hybrid unit 11.

In the description of the embodiment, the configuration of the hybrid unit 11 is assumed as being the same as and/or similar to that in the example in FIG. 3 for the sake of convenience, unless otherwise noted.

Each series element 15 may include at least two elements. Each series element 15 may partially or entirely be shared with a part of or all of an element other than the hybrid unit 11. The same applies to the parallel elements 17. In the example in FIG. 3, as will be described later, the capacitor C2 includes a dedicated capacitor C2a for the hybrid unit 11 and a parallel resonator 29P of the first filter 9. Specifically, the parallel resonator 29P of the first filter 9 is shared with the hybrid unit 11 as a part of the capacitor C2.

### 4. First Filter

### (4.1. Outline of First Filter)

For example, as mentioned above, the first filter 9 is a bandpass filter that allows a signal in a predetermined passband to pass therethrough. The passband (center frequency and bandwidth) is arbitrary. For example, the passband may be located within a range of 300 MHz to 10 GHz. The passband may comply with a predetermined standard. The passband may correspond with one passband defined by the standard, or may include at least two passbands defined by the standard.

A specific configuration of the first filter 9 may be any of various configurations, and may be, for example, a known configuration. More specifically, for example, the first filter 9 may be a piezoelectric filter including a piezoelectric body, a dielectric filter using an electromagnetic wave within a dielectric, an LC filter having a combination of an inductor and a capacitor, or a combination of two or more of the above. The piezoelectric filter may be, for example, an acoustic wave filter using an acoustic wave or a filter not using an acoustic wave (e.g., a filter using a piezoelectric vibrator).

An acoustic wave filter may be any of various types, so long as it uses an acoustic wave. For example, the acoustic wave filter may be an acoustic wave filter that excites an acoustic wave by using an IDT (interdigital transducer) electrode located on the surface of a piezoelectric body, or may be an acoustic wave filter (piezoelectric thin-film resonator) that excites an acoustic wave by using electrodes facing each other with a piezoelectric thin film interposed therebetween. For example, the acoustic wave filter may be a ladder filter including multiple acoustic wave resonators connected in a ladder pattern, a multi-mode filter (including a double-mode filter) including multiple IDT electrodes arranged in the propagation direction of an acoustic wave, or a transversal filter exchanging an acoustic wave between two IDT electrodes.

An acoustic wave is, for example, a SAW (surface acoustic wave), a BAW (bulk acoustic wave), an acoustic boundary wave, or a plate wave. However, these acoustic waves are not necessarily clearly distinguishable from one another.

For the sake of convenience, in the description of the embodiment, the first filter 9 described as an example is mainly a ladder filter in which acoustic wave resonators using IDT electrodes are connected in a ladder pattern. First, an example of an acoustic wave resonator will be described below with reference to FIG. 4. Then, a ladder filter will be described with reference to FIG. 5.

### (4.2. Example of Acoustic Wave Resonator)

FIG. 4 is a plan view schematically illustrating the configuration of an acoustic wave resonator 29 (sometimes simply referred to as “resonator 29” hereinafter).

With regard to the resonator 29, any of the directions thereof may be oriented upward or downward. In the following, an orthogonal coordinate system including a D1 axis, a D2 axis, and a D3 axis is added to the drawings for the sake of convenience, and terms, such as an upper surface, a lower surface, or the like, may sometimes be used with a +D3 side being the upper side. The D1 axis is defined as being parallel to the propagation direction of an acoustic wave propagating along the upper surface of the piezoelectric body, to be described later, the D2 is defined as being parallel to the upper surface of the piezoelectric body and orthogonal to the D1 axis, and the D3 axis is defined as being orthogonal to the upper surface of the piezoelectric body.

The resonator 29 includes a so-called one-port acoustic wave resonator. For example, the resonator 29 outputs a signal input from one of two terminals 28 schematically illustrated at both sides of the drawing from the other one of the two terminals 28. In this case, the resonator 29 performs a conversion from an electric signal to an acoustic wave and a conversion from an acoustic wave to an electric signal. Each terminal 28 may be regarded as an abstraction of an antenna terminal, a transmission terminal, a reception terminal, or a reference potential section to be described later with reference to FIG. 6.

The resonator 29 includes, for example, a piezoelectric substrate 31 (i.e., at least a part thereof at an upper surface 31a side), an IDT electrode 33 (i.e., an excitation electrode in a superordinate concept) located on the upper surface 31a, and a pair of reflectors 35 respectively located at opposite sides of the IDT electrode 33. Multiple resonators 29 may be provided on a single piezoelectric substrate 31. Specifically, the piezoelectric substrate 31 may be shared with the multiple resonators 29. In the following description, in order to distinguish the multiple resonators 29 sharing the single piezoelectric substrate 31 from each other, each combination (i.e., an electrode section of each resonator 29) of the IDT electrode 33 and the pair of reflectors 35 may sometimes be expressed as if the combination is the resonator 29 (i.e., as if the resonator 29 does not include the piezoelectric substrate 31) for the sake of convenience.

The piezoelectric substrate 31 at least has piezoelectricity in regions of the upper surface 31a where the resonators 29 are provided. As an example of such a piezoelectric substrate 31, the entire substrate includes a piezoelectric body. As another example, a so-called laminated substrate may be used. The laminated substrate includes a substrate (piezoelectric substrate) made of a piezoelectric body and having the upper surface 31a, and a support substrate bonded to the surface opposite the upper surface 31a of the piezoelectric substrate via an adhesive or directly bonded to the surface without the intervention of an adhesive. The support substrate may have or does not need to have a cavity at the lower side of the piezoelectric substrate. For example, the piezoelectric substrate 31 may include the support substrate and a film (piezoelectric film) made of a piezoelectric body or multiple films including a piezoelectric film provided in a partial region on the main surface at the +D3 side of the support substrate or on the entire main surface.

A piezoelectric body 31b included in a region of the piezoelectric substrate 31 at least provided with each resonator 29 is made of, for example, a single crystal having piezoelectricity. Examples of the material of such a single crystal include lithium tantalate (LiTaO₃), lithium niobate (LiNbO₃), and quartz crystal (SiO₂). A cut angle, a planar shape, and various dimensions may be set as appropriate.

The IDT electrode 33 and the reflectors 35 are each constituted by a layered conductor provided on the piezoelectric substrate 31. For example, the IDT electrode 33 and the reflectors 35 are made of the same material and have the same thickness. These layered conductors are, for example, metallic. The metal is, for example, Al or an alloy (Al alloy) containing Al as the main component. An example of the Al alloy is an Al—Cu alloy. Each layered conductor may include multiple metallic layers. The thickness of each layered conductor is appropriately set in accordance with the electrical properties and the like required in each resonator 29. As an example, the thickness of each layered conductor is not less than 50 nm and not more than 600 nm.

The IDT electrode 33 includes a pair of comb electrodes 37 (one of which is hatched for the sake of convenience to enhance visibility). Each comb electrode 37 includes, for example, a bus bar 39, multiple electrode fingers 41 extending parallel to each other from the bus bar 39, and multiple dummy electrodes 43 protruding from the bus bar 39 and located between the multiple electrode fingers 41. The pair of comb electrodes 37 is disposed such that the multiple electrode fingers 41 engage with each other (i.e., overlap each other).

For example, the bus bar 39 substantially has a long shape extending linearly in the acoustic-wave propagation direction (D1 direction) while having a fixed width. The pair of bus bars 39 is opposed to each other in the direction (D2 direction) orthogonal to the acoustic-wave propagation direction. The bus bars 39 may each have a varying width and/or may be inclined relative to the acoustic-wave propagation direction.

For example, each electrode finger 41 substantially has a long shape extending linearly in the direction (D2 direction) orthogonal to the acoustic-wave propagation direction while having a fixed width. Each electrode finger 41 may have a varying width. In each comb electrode 37, the multiple electrode fingers 41 are arranged in the acoustic-wave propagation direction. The multiple electrode fingers 41 of one of the comb electrodes 37 and the multiple electrode fingers 41 of the other comb electrode 37 are basically alternately arranged.

A pitch p (e.g., a center-to-center distance between two neighboring electrode fingers 41) of the multiple electrode fingers 41 is basically fixed within the IDT electrode 33. Alternatively, the IDT electrode 33 may be partially provided with a narrow pitch section where the pitch p is narrower than the other majority section or a wide pitch section where the pitch p is wider than the other majority section. The IDT electrode 33 may also be partially provided with a thinned-out section where at least one electrode finger 41 is substantially thinned out.

In the description of the embodiment, the term “pitch p” refers to the pitch in a section (i.e., the majority of the multiple electrode fingers 41) excluding a unique section, such as the narrow pitch section, the wide pitch section, or the thinned-out section mentioned above, unless otherwise noted. If the pitch varies in the majority of electrode fingers 41 excluding the unique section, an average value of the pitches of the majority of electrode fingers 41 (e.g., 80% of all the fingers selected to achieve minimal dispersion) may be used as the value of the pitch p.

The number of electrode fingers 41 may be appropriately set in accordance with the electrical properties and the like required in each resonator 29. Since FIG. 4 is a schematic view, the number of electrode fingers 41 illustrated is small. In actuality, the number of electrode fingers 41 arranged may be larger than the number illustrated. The same applies to strip electrodes 47 of the reflectors 35 to be described later.

The multiple electrode fingers 41 have, for example, the same length. The IDT electrode 33 may be given a so-called apodization treatment in which the length of the multiple electrode fingers 41 (i.e., an overlap width W from a different viewpoint) varies depending on the location in the propagation direction. The length and the width of each electrode finger 41 may be appropriately set in accordance with the required electrical properties and the like.

For example, the dummy electrodes 43 substantially have a fixed width and protrude in the direction orthogonal to the acoustic-wave propagation direction. The width is, for example, equal to the width of each electrode finger 41. The multiple dummy electrodes 43 are arranged at a pitch equal to that of the multiple electrode fingers 41. The tip of each dummy electrode 43 of one of the comb electrodes 37 is opposed to the tip of the corresponding electrode finger 41 of the other comb electrode 37 with a gap therebetween. The IDT electrode 33 does not need to include the dummy electrodes 43.

The pair of reflectors 35 is located at the opposite sides of the IDT electrode 33 in the acoustic-wave propagation direction. For example, each reflector 35 may be in an electrically floating state or may be supplied with a reference potential. Each reflector 35 is, for example, lattice-shaped. In other words, each reflector 35 includes a pair of bus bars 45 opposed to each other and multiple strip electrodes 47 extending between the pair of bus bars 45. The pitch between the multiple strip electrodes 47 and the pitch between the electrode finger 41 and the strip electrode 47 that are adjacent to each other are basically equal to the pitch between the multiple electrode fingers 41.

When a voltage is applied to the pair of comb electrodes 37, the multiple electrode fingers 41 apply the voltage to the piezoelectric body 31b, and the piezoelectric body 31b vibrates. In other words, the acoustic wave is excited. Specifically, of acoustic waves of various wavelengths propagating in various directions, an acoustic wave with the pitch p between the multiple electrode fingers 41 as substantially a half wavelength (2/2) and propagating in the arrangement direction of the multiple electrode fingers 41 tends to have an increased amplitude since multiple waves excited by the multiple electrode fingers 41 overlap each other with the same phase.

The acoustic wave propagating through the piezoelectric body 31b is converted into an electric signal by the multiple electrode fingers 41. In this case, the intensity of the electric signal converted from the acoustic wave with the pitch p between the multiple electrode fingers 41 as substantially the half wavelength (λ/2) and propagating in the arrangement direction of the multiple electrode fingers 41 tends to increase, identically and/or similarly to when the acoustic wave is excited.

In accordance with the above-described operation (and other non-described operations), each resonator 29 functions as a resonator in which the frequency of the acoustic wave with the pitch p as substantially the half wavelength (λ/2) serves as a resonant frequency. The pair of reflectors 35 contributes to confinement of the acoustic wave.

Although not particularly illustrated, each resonator 29 may include a protective film (not illustrated) covering the upper surface 31a of the substrate 31 from above the IDT electrode 33 and the reflectors 35. For example, such a protective film is made of an insulative material, such as SiO₂, and contributes to reducing the probability of corrosion of the IDT electrode 33 and/or the like and/or compensating for a property change occurring due to a temperature change in the resonator 29. The resonator 29 may also include an additional film overlying the upper surface or the lower surface of the IDT electrode 33 and the reflectors 35 and basically having a shape that is within the IDT electrode 33 and the reflectors 35 in plan view. Such an additional film is made of an insulative material or metallic material having acoustic properties different from the material of the IDT electrode 33 and/or the like and contributes to an improved acoustic-wave reflection coefficient.

### (4.3. Ladder Filter)

FIG. 5 is a plan view illustrating a ladder filter as an example of the first filter 9. As is apparent from the orthogonal coordinate system D1 D2 D3, this drawing illustrates the upper surface 31a of the piezoelectric substrate 31 (piezoelectric body 31b), identically and/or similarly to FIG. 4. From a different viewpoint, FIG. 5 may be regarded as a schematic plan view of the piezoelectric substrate 31 including the chip 5, as viewed from the multilayer substrate 3 side.

Of a signal input to an input terminal 49I, the first filter 9 outputs a signal having a frequency within a predetermined passband to an output terminal 49O. A signal having a frequency outside the passband is released to a GND terminal 49G supplied with a reference potential. These terminals may collectively be referred to as “terminals 49”.

The first filter 9 includes multiple resonators 29 (29S and 29P) connected in a ladder pattern. Specifically, the first filter 9 includes multiple (one is also permissible) series resonators 29S series-connected between the input terminal 49I and the output terminal 49O, and multiple (one is also permissible) parallel resonators 29P (parallel arm) parallel-connected between a series line (series arm 51) and the GND terminal 49G (reference potential section). Each parallel resonator 29P is connected to the input terminal 49I side or the output terminal 49O side of the any one of the series resonators 29S. Specifically, the multiple parallel resonators 29P connect multiple electrically-different positions of the series arm 51 to the GND terminal 49G.

Although not particularly illustrated, each resonator 29 has a minimum impedance value at a resonant frequency and a maximum impedance value at an anti-resonant frequency. In the multiple series resonators 29S, the resonant frequency is substantially the same, and the anti-resonant frequency is substantially the same. In the multiple parallel resonators 29P, the resonant frequency is substantially the same, and the anti-resonant frequency is substantially the same. The resonant frequency of the series resonators 29S and the anti-resonant frequency of the parallel resonators 29P are substantially equal to each other.

With the above connection relationship and the above settings of the resonant frequency and the anti-resonant frequency, a bandpass filter is achieved. The center frequency of the passband is substantially equal to the resonant frequency of the series resonators 29S and the anti-resonant frequency of the parallel resonators 29P. The width of the passband is slightly narrower than the width from the resonant frequency of the parallel resonators 29P to the anti-resonant frequency of the series resonators 29S.

The number of series resonators 29S and the number of parallel resonators 29P are arbitrary. The first filter 9 may include (as in the illustrated example) or does not need to include the parallel resonator 29P connected to the input terminal 49I side relative to the series resonator 29S electrically closest to the input terminal 49I. Likewise, the first filter 9 may include (as in the illustrated example) or does not need to include the parallel resonator 29P connected to the output terminal 49O side relative to the series resonator 29S electrically closest to the output terminal 49O.

Although not particularly illustrated, each series resonator 29S may be split into two or more. For example, each series resonator 29S may include multiple series-connected resonators 29. Likewise, each parallel resonator 29P may be split into two or more. Specific locations of the series resonators 29S and the parallel resonators 29P on the upper surface 31a of the piezoelectric body 31b, the shape and size of each resonator 29, and the like may be appropriately set in accordance with the properties and the like required in the first filter 9. The first filter 9 may include a component other than the resonators 29. For example, the first filter 9 may include an inductor or capacitor series-connected or parallel-connected to each resonator 29.

### 5. Chip

For example, the majority of the chip 5 may include the piezoelectric substrate 31. In detail, for example, the chip 5 may include the piezoelectric substrate 31 and a relatively thin layer overlapping the surface of the piezoelectric substrate 31. Examples of the relatively thin layer include a conductive layer (such as the IDT electrode 33) overlapping the upper surface 31a of the piezoelectric substrate 31 and a protective layer (not illustrated) covering the majority of the upper surface 31a from above the conductive layer. The protective layer does not cover the terminals (49I, 49O, and 49G). The chip 5 may include a layer covering a side surface or the lower surface of the piezoelectric substrate 31.

For example, the chip 5 having the configuration described in the previous paragraph is mounted on the multilayer substrate 3 while the upper surface 31a faces the upper surface of the multilayer substrate 3 (i.e., the upper surface in FIG. 1). In this case, the terminals 49 of the chip 5 and the pads 25 of the multilayer substrate 3 face each other, and are bonded to each other by a conductive bonding material (not illustrated) interposed therebetween. A space with a height substantially equivalent to the thickness of the bonding material bonding the terminals 49 and the pads 25 to each other is provided between the chip 5 and the multilayer substrate 3 (i.e., above the resonators 29 from a different viewpoint).

For example, although not particularly illustrated, in addition to the above-described components, the chip 5 may include a box-shaped insulative cover covering the upper surface 31a of the piezoelectric substrate 31. With the cover, a space is provided above the resonators 29. The chip 5 includes, for example, columnar terminals located on the terminals 49 and extending through the cover. The chip 5 is mounted on the multilayer substrate 3 while the upper surface of the cover faces the upper surface (i.e., the upper surface in FIG. 1) of the multilayer substrate 3. In this case, the upper surfaces of the columnar terminals and the pads 25 of the multilayer substrate 3 face each other, and are bonded to each other by a conductive bonding material (not illustrated) interposed therebetween.

For example, as in the example in FIG. 5, one chip 5 may include one first filter 9. One chip 5 may include only a part of one first filter 9. For example, multiple series resonators 29S and multiple parallel resonators 29P included in the same first filter 9 may be provided in a different chip 5. One chip 5 may include at least two first filters 9. The number of terminals 49 included in one chip 5 may be appropriately set in accordance with the differences in configuration as described above.

### 6. Part of Hybrid Unit Located in Multilayer Substrate

FIG. 2 is a perspective view illustrating a part of the hybrid unit 11 located in the multilayer substrate 3. In this drawing, the contour of the multilayer substrate 3 is indicated with a dotted line, whereas a conductor constituting a part of the hybrid unit 11 is indicated with a solid line.

The part of the hybrid unit 11 located in the multilayer substrate 3 may be arbitrarily selected. In the example in FIG. 2, the multilayer substrate 3 includes four series elements 15 (i.e., four inductors L). In other words, the multilayer substrate 3 does not include four parallel elements 17 (i.e., four capacitors C).

Unlike the illustrated example, the multilayer substrate 3 may include, for example, one to three of the four series elements 15 (in other words, does not need to include one to three of the series elements 15). For example, the multilayer substrate 3 may include one to four of the four parallel elements 17 so long as it does not include the entire hybrid unit 11. In the multilayer substrate 3, the combination of the number of series elements 15 and the number of parallel elements 17 is arbitrary.

Unlike the illustrated example, the multilayer substrate 3 may include a part of one series element 15 and a part of one parallel element 17. For example, the capacitance required by the capacitor C1 may be achieved with a combined capacitance of the capacitance of a capacitor provided in the multilayer substrate 3 and the capacitance of a capacitor provided in the chip 5. An adjustment according to the operating frequency may be achieved with, for example, the capacitance of the capacitor provided in the chip 5.

The series elements 15 and/or the parallel elements 17 included in the multilayer substrate 3 (i.e., contained in the multilayer substrate 3) may have any specific configuration. For example, the series elements 15 and/or the parallel elements 17 may be built in the multilayer substrate 3, may be chips embedded in the multilayer substrate 3, or may be a combination of both. A more specific example of the series elements 15 and/or the parallel elements 17 built in the multilayer substrate 3 may include conductor layers (not given a reference sign) overlapping the insulative layers 21a (FIG. 1) and/or via conductors (not given a reference sign) extending through the insulative layers 21a.

In the description of the embodiment, the elements (such as 15 and 17) included in the multilayer substrate 3 refer to, for example, elements inseparable from the multilayer substrate 3 unless breaking the multilayer substrate 3, unless otherwise noted. Therefore, for example, an element (e.g., chip) mounted on the surface of the multilayer substrate 3 by using a conductive bonding material is not included in the elements included in the multilayer substrate 3. The elements included in the multilayer substrate 3 may entirely be located inside the multilayer substrate 3 or may partially be exposed to the outside of the multilayer substrate 3.

When the inductors and/or the capacitors are built in the multilayer substrate 3, the inductors and/or capacitors may have any specific configuration. For example, each inductor may include a helically-extending conductor, a spirally-extending layered conductor, or a meanderingly-extending layered conductor. Each capacitor may include two layers of layered conductors (parallel flat plates) facing each other with the insulative layers 21a interposed therebetween, layered conductors (parallel flat plates) located in the same layer and opposed to each other on the surface of the insulative layers 21a, or a pair of comb electrodes (see the IDT electrode 33) located on the surface of the insulative layers 21a. From a different viewpoint, the inductors and/or the capacitors may be three dimensional or two dimensional.

In the example in FIG. 2, the inductors L1 to L4 are built in the multilayer substrate 3. In detail, the multilayer substrate 3 has three-dimensional coils in which the stacking direction of the multiple insulative layers 21a (FIG. 1) is set as the axial direction. More specifically, although not particularly given reference signs, each inductor includes multiple conductor layers extending circularly for less than one turn (half a turn in the illustrated drawing) between multiple insulative layers 21a, and multiple via conductors extending through the multiple insulative layers 21a and connecting the multiple conductor layers to each other. Unlike the illustrated example, the three-dimensionally-coiled inductors L1 to L4 built in the multilayer substrate 3 may each include a conductor layer and a via conductor in which the direction extending along the insulative layers 21a is set as the axial direction.

Sections among the four inductors L serve as the ports 19. In FIG. 2, four via conductors extending upward from four layered wiring lines (not given reference signs) series-connecting the four inductors L are respectively given the reference signs of the ports 19A to 19D for the sake of convenience. However, from an electrical viewpoint (neglecting the inductance and the like of each wiring line), in addition to the aforementioned four via conductors, arbitrary positions of the aforementioned four layered wiring lines or conductors (not illustrated) connected to the upper ends of the via conductors may be regarded as the ports 19A to 19D.

### 7. Part of Hybrid Unit Located in Chip

A part of the hybrid unit 11 located in the chip 5 may be arbitrarily selected. A description of an example of this arbitrarily selected part will be omitted since it is a reversal of the description about the example of the part selected as the aforementioned part of the hybrid unit 11 located in the multilayer substrate 3. For the sake of convenience, the description of the embodiment mainly refers to a configuration where the capacitors C1 to C4 as the parallel elements 17 of the hybrid unit 11 are located in the chip 5, and is assumed based on such a configuration, unless otherwise noted.

The series elements 15 and/or the parallel elements 17 included in the chip 5 may have any specific configuration. For example, the series elements 15 and/or the parallel elements 17 may be built in or embedded in a substrate (e.g., the piezoelectric substrate 31) included in the chip 5, identically and/or similarly to when the series elements 15 and/or the parallel elements 17 are provided in the multilayer substrate 3. Unlike the multilayer substrate 3, the elements (15 and/or 17) may be chips mounted on the surface of the substrate (e.g., the piezoelectric substrate 31) included in the chip 5. In a configuration where the chip 5 includes a cover covering the piezoelectric substrate 31, as mentioned above, the elements (15 and/or 17) may include conductors (conductor layers and/or through conductors) located on the surface of the cover and/or inside the cover. The elements (15 and/or 17) may be realized by a combination of the various aforementioned components. In any case, the series elements 15 and/or the parallel elements 17 included in the chip 5 are electrically connected to the remaining hybrid unit 11 when the chip 5 is mounted on the multilayer substrate 3.

When the inductors and/or capacitors are built in the piezoelectric substrate 31 or the cover covering the piezoelectric substrate 31, the inductors and/or the capacitors may have any specific configuration, identically and/or similarly to when the inductors and/or capacitors are built in the multilayer substrate 3. For example, the inductors may each be helical, spiral, or meandering, and the capacitors may each be two layers of parallel flat plates, parallel flat plates within a single layer, or a pair of comb electrodes.

In the example illustrated in FIG. 5, the capacitor C2 as a parallel element 17 is constituted by a conductor located on the upper surface of the piezoelectric substrate 31 (piezoelectric body 31b). In detail, the capacitor C2 includes a capacitor C2a and a capacitor C2b.

In the illustration in FIG. 5, it is assumed that the output terminal 49O of the multiple terminals 49 is a terminal directly connected to the part (loop 13) of the hybrid unit 11 located in the multilayer substrate 3 (without the intervention of another filter and another hybrid unit). Specifically, the output terminal 49O is directly connected to any of the ports 19A to 19D. For the sake of convenience, it is assumed that the output terminal 49O is connected to the port 19B in accordance with FIG. 3. The capacitor C2 is connected to the output terminal 49O side relative to the series resonator 29S located closest to the output terminal 49O (i.e., the port 19B from a different viewpoint). Accordingly, the capacitor C2 functions as a parallel element 17 included in the hybrid unit 11.

Because the capacitors C2a and C2b are both connected to the output terminal 49O side relative to the series resonator 29S located closest toward the output terminal 49O, the combined capacitance of the two capacitors is the capacitance of the parallel element 17 (capacitor C2). More specifically, because the capacitors C2a and C2b are parallel-connected between the output terminal 49O (port 19B) and the GND terminal 49G, the sum of the capacitances of the capacitors C2a and C2b is the capacitance of the capacitor C2.

In the example in FIG. 5, for example, a position where the capacitor C2a is connected to the series arm 51 is close to the output terminal 49O relative to a position where the capacitor C2b is connected to the series arm 51 (illustrated example). Unlike the illustrated example, the former position may be the same as the latter position or may be farther from the output terminal 49O. For example, a wiring line extending from the series arm 51 may bifurcate and extend to the capacitors C2a and C2b.

In the example in FIG. 5, for example, the capacitors C2a and C2b are independently connected to the same GND terminal 49G. Unlike the illustrated example, wiring lines extending from the capacitors C2a and C2b may merge and extend to the GND terminal 49G. The capacitors C2a and C2b may be connected to different GND terminals 49G.

In the example in FIG. 5, the capacitor C2a is constituted by a pair of comb electrodes (not given reference signs) that are the same as and/or similar to the IDT electrode 33. However, since the capacitor C2a does not use an acoustic wave, the arrangement direction of the multiple electrode fingers does not need to be parallel to the acoustic-wave propagation direction (D1 direction). In the illustrated example, the arrangement direction of the multiple electrode fingers in the capacitor C2a is orthogonal to the acoustic-wave propagation direction. As a precautionary indication, the arrangement direction of the multiple electrode fingers in the capacitor C2a may be parallel to the acoustic-wave propagation direction or may be inclined relative thereto at an angle smaller than 90°.

Since the capacitor C2a does not use an acoustic wave, the capacitor C2a does not need to be provided with reflectors at opposite sides of the pair of comb electrodes (illustrated example), unlike the IDT electrode 33 of each resonator 29. Alternatively, unlike the illustrated example, in order to reduce the probability in which an acoustic wave generated in the capacitor C2a has an unintentional effect on the resonator 29 and the like, one or two reflectors may be provided adjacent to the capacitor C2a. The capacitor C2a does not need to include the dummy electrodes 43, and the pitch of the electrode fingers may be set arbitrarily. For example, the pitch of the capacitor C2a may be smaller than the pitch of the acoustic wave resonator.

For example, the pair of comb electrodes of the capacitor C2a is made of the same material and have the same thickness as the IDT electrode 33 of each resonator 29. Alternatively, the material and the thickness may be different between the two.

The capacitor C2b is constituted by the IDT electrode 33 of the parallel resonator 29P. Specifically, the parallel resonator 29P connected to the output terminal 49O side relative to the series resonator 29S closest to the output terminal 49O is shared with the capacitor C2b.

Unlike the illustrated example, the capacitor C2 may be constituted by the capacitor C2a alone that is not shared with the first filter 9, or may be constituted by the capacitor C2b alone that is shared with the first filter 9.

### 8. Example of Circuit Configuration of Entire Filter Device 1

### (8.1. Basic Points of Circuit Configuration)

The circuit configuration (excluding the structure-related matter, such as the parallel elements 17 provided in the chip 5) of the entire filter device 1 including the first filter 9 and the hybrid unit 11 described above may be any of various types, and may be, for example, the same as and/or similar to a known type. An example of the circuit configuration of the entire filter device 1 will be described below.

FIG. 6 is a schematic view illustrating the example of the circuit configuration of the entire filter device 1.

The filter device 1 illustrated in FIG. 6 serves as a branching filter (more specifically, a duplexer). For example, the filter device 1 includes a transmission path 2T that filters a transmission signal from a transmission terminal 7T and outputs the transmission signal to an antenna terminal 7A, and a reception path 2R that filters a reception signal from the antenna terminal 7A and outputs the reception signal to a reception terminal 7R. The transmission terminal 7T, the reception terminal 7R, and the antenna terminal 7A are examples of the external terminals 7 illustrated in FIG. 1.

The transmission path 2T includes a transmission filter system 12 responsible for directly filtering the transmission signal. The transmission filter system 12 includes transmission filters 9TA and 9TB (sometimes simply referred to as “transmission filters 9T” without being distinguished from each other). The reception path 2R includes a reception filter system 14 responsible for directly filtering the reception signal. The reception filter system 14 includes a reception filter 9R. Each of the transmission filters 9T and the reception filter 9R is an example of the first filter 9. The transmission filter system 12 (transmission filters 9T) corresponds to a transmission band. The reception filter system 14 (reception filter 9R) corresponds to a reception band. In other words, the passbands of the transmission filters 9T and the reception filter 9R are different from each other (i.e., do not overlap each other).

The filter device 1 includes a first hybrid unit 11A and a second hybrid unit 11B. Each of the first hybrid unit 11A and the second hybrid unit 11B is an example of the hybrid unit 11. The first hybrid unit 11A is interposed among the antenna terminal 7A, the transmission filters 9TA and 9TB, and the reception filter 9R. The second hybrid unit 11B is interposed among the transmission terminal 7T, the transmission filters 9TA and 9TB, and a termination resistor 61. A signal path extending through the transmission filter 9TA and a signal path extending through the transmission filter 9TB are provided between the first hybrid unit 11A and the second hybrid unit 11B.

The first hybrid unit 11A and the second hybrid unit 11B distribute, perform phase adjustment on, and/or combine the transmission signal and/or the reception signal. In this process, for example, nonlinear distortions occurring in the transmission filters 9T and/or the reception filter 9R are distributed, the distributed nonlinear distortions are given opposite phases from each other, and the nonlinear distortions with the opposite phases are subsequently combined to cancel out each other. Specifically, the nonlinear distortions are reduced. On the other hand, the filter device 1 basically maintains the intensities of the transmission signal and the reception signal.

The specific connection relationship in the above-described circuit configuration and the principle of the above-described advantages are described in Patent Literature 1. Therefore, only the relevant points of the circuit configuration in the illustrated example will be simply described.

The transmission filters 9TA and 9TB correspond to the same passband (transmission band). Specifically, the passbands of the two are identical to each other substantially and/or in design. The transmission filters 9TA and 9TB have identical or similar configurations and have properties identical to each other substantially or in design. Alternatively, the transmission filters 9TA and 9TB may be finely adjusted to have slightly different passbands and/or slightly different properties.

In the first hybrid unit 11A, the port 19A is connected to the antenna terminal 7A. The port 19B is connected to the reception filter 9R. The port 19C is connected to the transmission filter 9TA. The port 19D is connected to the transmission filter 9TB.

In the second hybrid unit 11B, the port 19A is connected to the transmission filter 9TA. The port 19B is connected to the transmission filter 9TB. The port 19C is connected to the termination resistor 61. The port 19D is connected to the transmission terminal 7T.

From a different viewpoint, the transmission filter system 12 is connected to the antenna terminal 7A via the first hybrid unit 11A, and is connected to the transmission terminal 7T via the second hybrid unit 11B. The reception filter system 14 is connected to the antenna terminal 7A via the first hybrid unit 11A, and is directly connected to the reception terminal 7R.

When a signal (e.g., a transmission signal) is input to the transmission terminal 7T from the outside, the second hybrid unit 11B distributes two signals phase-shifted by 90° from each other to the transmission filters 9TA and 9TB. The two distributed signals pass through the transmission filters 9TA and 9TB and are subsequently input to the first hybrid unit 11A. The two signals input to the first hybrid unit 11A are turned into signals with the same phase and are output to the antenna terminal 7A.

On the other hand, the aforementioned two signals input to the first hybrid unit 11A are (ideally) not output to the reception filter 9R. This is because the two signals are given opposite phases when traveling toward the port 19B and cancel out each other. Although the above description relates to the transmission signal as an example, nonlinear distortions occurring in the transmission filters 9T cancel out each other in the same and/or similar manner.

When a signal (e.g., a reception signal) is input to the antenna terminal 7A from an antenna, the first hybrid unit 11A distributes two signals phase-shifted by 90° from each other to the transmission filters 9TA and 9TB. The two distributed signals are reflected by the transmission filters 9TA and 9TB and are returned to the first hybrid unit 11A. The two signals returned to the first hybrid unit 11A are turned into signals with the same phase and are output to the reception filter 9R.

The aforementioned two signals returned to the first hybrid unit 11A are (ideally) not output to the antenna terminal 7A, and an insertion loss by the first hybrid unit 11A does not occur. This is because the two signals are given opposite phases when traveling toward the port 19A and cancel out each other.

As described above, the signal input to the antenna terminal 7A is reflected by the transmission filter system 12 and is output to the reception filter 9R. Even with such a configuration, the reception filter 9R is expressed as being connected to the antenna terminal 7A via the first hybrid unit 11A in the present disclosure.

The termination resistor 61 has, for example, a predetermined resistance value and connects the second hybrid unit 11B to the reference potential section. Accordingly, for example, reflection of a signal flowing from the port 19A and/or the port 19B to the port 19C is reduced. Although not particularly illustrated, the filter device 1 may include a matching circuit for impedance matching at an appropriate location.

Although not particularly illustrated, the following includes other examples of the circuit configuration of the entire filter device 1. With regard to any of the following examples, since the specific configuration and the advantages are described in Patent Literature 1, only the relevant points will be described here.

For example, in the example in FIG. 6, the configuration of the transmission side and the configuration of the reception side may be inverted. Specifically, the two terminals indicated as the reception terminal 7R and the transmission terminal 7T in FIG. 6 may respectively be a transmission terminal 7T and a reception terminal 7R, the filter indicated as the reception filter 9R in FIG. 6 may be a transmission filter 9T, and the two filters indicated as the two transmission filters 9T in FIG. 6 may be two reception filters 9R.

In this case, when a signal (e.g., a reception signal) is input to the antenna terminal 7A from the antenna, the first hybrid unit 11A distributes signals phase-shifted by 90° from each other to the two reception filters 9R. The distributed signals pass through the two reception filters 9R, are subsequently turned into signals with the same phase by the second hybrid unit 11B, and are output to the reception terminal 7R.

For example, the example in FIG. 6 and the above-described non-illustrated example may be combined. In detail, a new termination resistor is connected to the port 19B of the first hybrid unit 11A. Moreover, two second hybrid units 11B are provided. Identically and/or similarly to the example in FIG. 6, the ports 19C and 19D of one of the second hybrid units 11B connect the ports 19C and 19D of the first hybrid unit 11A to the transmission terminal 7T and the termination resistor 61 via the two transmission filters 9T. Identically and/or similarly to the above-described non-illustrated example, the ports 19C and 19D of the other one of the second hybrid units 11B connect the ports 19C and 19D of the first hybrid unit 11A to the reception terminal 7R and the termination resistor 61 via the two reception filters 9R.

In the illustrated example, the first filter 9 receives an unbalanced signal and outputs the unbalanced signal. For example, the unbalanced signal may be regarded as one signal whose signal level changes relative to the reference potential. Alternatively, the first filter 9 may receive a balanced signal and/or output the balanced signal. For example, the balanced signal may be regarded as two signals with opposite phases from each other.

### (8.2. Distribution of Filter Device to Multilayer Substrate and Chip)

The lower part of FIG. 6 indicates whether each component of the filter device 1 is provided in either of the multilayer substrate 3 and the chip 5, as indicated by the reference signs of the multilayer substrate 3 and the chip 5.

Although the reference sign of the multilayer substrate 3 is indicated at multiple locations, the number of multilayer substrates 3 is one, as is apparent from the above description. Alternatively, unlike the illustration in FIG. 6, the filter device 1 illustrated in FIG. 1 may include only a part of the circuit configuration illustrated in FIG. 6. Specifically, unlike the above description, there may be two or more multilayer substrates 3.

As is apparent from the above description, the number of chips 5 is arbitrary. For example, one chip 5 alone may be provided in correspondence with all of the first filters 9, one chip 5 may be provided for every first filter 9, one chip 5 may be provided in correspondence with each of the transmission filter system 12 and the reception filter system 14 (i.e., a total of two chips 5), or a single first filter 9 may be distributed to two or more chips 5.

For example, the chip 5 includes at least a part of the first filter 9. Therefore, a range (i.e., the rightmost chip 5 in FIG. 6) given the reference sign of the chip 5 and not including the first filter 9 does not imply a chip not including the first filter 9, but indicates any of the chips 5 including the first filter 9. The range simply does not include the first filter 9 in the illustration of FIG. 6. Unlike the above description, there may be a chip 5 not including the first filter 9.

In the configuration where the filter device 1 includes at least two hybrid units 11, as in the example in FIG. 6, a technical matter where a hybrid unit 11 is partially included in the chip 5 may be applied to either of the hybrid units 11. In the illustrated example, the technical matter where a hybrid unit 11 is partially included in the chip 5 is applied to both of the first hybrid unit 11A and the second hybrid unit 11B (i.e., all of the hybrid units 11 included in the filter device 1 from a different viewpoint).

It is apparent from FIG. 6 that the four ports 19 of each hybrid unit 11 are connected directly (i.e., without the intervention of the first filter 9 or another hybrid unit 11) to the external terminals 7, or are connected to first filters 9 having different roles. The parallel elements 17 (e.g., capacitors) that are partially or entirely provided in the chip 5 may be connected to any of the aforementioned various ports. From a different viewpoint, a technical matter where the parallel elements 17 are partially or entirely provided in the chip 5 may be applied to any number of ports among the four ports 19. In the illustrated example, the aforementioned matter is applied to all of the ports 19.

For example, as illustrated in FIG. 5, the parallel elements 17 connected to the ports 19 (e.g., the ports 19B and 19C of the first hybrid unit 11A) directly connected to the first filter 9 may be connected to the terminals 49 for connecting the first filter 9 to the multilayer substrate 3 (i.e., the ports 19 from a different viewpoint). For example, the parallel element 17 connected to the port 19 (e.g., the port 19A of the first hybrid unit 11A) directly connected to the external terminal 7 may be connected to the terminal 49 provided for the parallel element 17. More specifically, for example, although not particularly illustrated, in addition to the first filter 9, the chip 5 may include a terminal 49 connecting the terminal 49 connected to the port 19 and the external terminal 7 to each other, and a wiring line connecting the two to each other. The parallel element 17 may connect the aforementioned wiring line to the GND terminal 49G.

Unlike the illustrated example, the parallel element 17 connected to the port 19 directly connected to the external terminal 7 may be provided outside the filter device 1. For example, the aforementioned parallel element 17 may be provided at a circuit board (not illustrated) on which the filter device 1 is mounted, and the external terminal 7 and a reference potential section included in the circuit board (not illustrated) may be connected to each other. It is not impossible that any of the parallel elements 17 connected to the ports 19 directly connected to the first filter 9 be provided outside the filter device 1.

The four parallel elements 17 (capacitors C1 to C4) included in a single hybrid unit 11 may be provided in the same chip 5, or may be provided in different chips 5. For example, in a configuration where one chip 5 is provided for every first filter 9, the capacitor C2 of the first hybrid unit 11A may be provided in the chip 5 including the reception filter 9R, the capacitor C4 of the first hybrid unit 11A may be provided in the chip 5 including the transmission filter 9TA, and the capacitor C3 of the first hybrid unit 11A may be provided in the chip 5 including the transmission filter 9TB.

In the illustrated example, the termination resistor 61 is provided in the chip 5. Alternatively, the termination resistor 61 may be provided in the multilayer substrate 3. The reference potential section to which the parallel elements 17 are connected may be any of various conductors of the multilayer substrate 3, various conductors of the chip 5, or various conductors of the circuit board (not illustrated) on which the filter device 1 is mounted, so long as it is assumed that a reference potential is supplied to the reference potential section. The term “reference potential section” may be a term indicating all of the aforementioned various conductors, or may indicate the various conductors, unless otherwise noted or so long as an inconsistency and the like does not occur.

### 9. Communication Apparatus Including Filter Device

FIG. 7 is a block diagram illustrating a relevant part of a communication apparatus 151 as an application example of the filter device 1. The communication apparatus 151 includes a module 171 and a housing 173 accommodating the module 171. The module 171 performs wireless communication using a radio wave, and includes the filter device 1. In the filter device 1, only the transmission filter system 12 and the reception filter system 14 are schematically illustrated.

In the module 171, a transmission information signal TIS containing information to be transmitted is turned into a transmission signal TS by being modulated and increased in frequency (i.e., converted into a radio-frequency signal having a carrier-wave frequency) by an RF-IC (radio-frequency integrated circuit) 153 (an example of an integrated circuit element). The transmission signal TS has an unwanted component outside a transmission passband removed therefrom by a bandpass filter 155, is amplified by an amplifier 157, and is input to the filter device 1 (transmission terminal 7T). Then, the filter device 1 (transmission filter system 12) removes the unwanted component outside the transmission passband from the input transmission signal TS, and outputs the transmission signal TS after the removal from the antenna terminal 7A to an antenna 159. The antenna 159 converts the input electric signal (transmission signal TS) into a wireless signal (radio wave), and transmits the wireless signal.

In the module 171, the wireless signal (radio wave) received by the antenna 159 is converted into an electric signal (reception signal RS) by the antenna 159 and is input to the filter device 1 (antenna terminal 7A). The filter device 1 (reception filter system 14) removes an unwanted component outside a reception passband from the input reception signal RS, and outputs the reception signal RS from the reception terminal 7R to an amplifier 161. The output reception signal RS is amplified by the amplifier 161, and has the unwanted component outside the reception passband removed therefrom by a bandpass filter 163. Then, the reception signal RS is turned into a reception information signal RIS by being decreased in frequency and demodulated by the RF-IC 153.

Each of the transmission information signal TIS and the reception information signal RIS may be a low-frequency signal (baseband signal) containing appropriate information, and is, for example, an analog audio signal or a digitalized audio signal. The passband of the wireless signal may be appropriately set. The modulation method may be phase modulation, amplitude modulation, frequency modulation, or a combination of two or more of the above. Although a direct conversion system is illustrated as the circuit system, another appropriate system may be used. For example, a double super-heterodyne system may be used. FIG. 7 schematically illustrates only the relevant part. A low-pass filter, an isolator, and/or the like may be added to appropriate locations, and/or the location of the amplifier and/or the like may be changed.

In the module 171, the components from the RF-IC 153 to the antenna 159 are, for example, mounted on or contained in the same circuit board. Accordingly, the filter device 1 is turned into a module by being combined with other components. Instead of being turned into a module, the filter device 1 may be included in the communication apparatus 151. The components illustrated as the components of the module 171 may be located outside the module or may be unaccommodated in the housing 173. For example, the antenna 159 may be exposed to the outside of the housing 173.

### 10. Overview of Embodiment

As described above, the filter device 1 includes the multilayer substrate 3, the chip 5 mounted on the multilayer substrate 3, the first filter 9 at least partially included in the chip 5, and the first hybrid coupler (hybrid unit 11) connected to the first filter 9. The hybrid unit 11 has a part (e.g., the loop 13) included in the multilayer substrate 3 and another part (e.g., at least one parallel element 17) included in the chip 5.

In this case, for example, as mentioned in the beginning of the description of the embodiment, the chip 5 can adjust the operating frequency to configure the hybrid unit 11 having the operating frequency according to the passband of the first filter 9 included in the chip 5. As a result, the multilayer substrate 3 can be commonly used for different passbands (i.e., different chips 5), thereby achieving enhanced productivity. For example, although dependent on the configuration of the multilayer substrate 3, each capacitor C is configured by utilizing the piezoelectric body 31b of the chip 5 having a higher dielectric constant than the multilayer substrate 3, whereby the filter device 1 can be reduced in size.

The first hybrid coupler (hybrid unit 11) may include the four series elements 15 series-connected to one another and electrically constituting the loop 13, the four ports 19 electrically positioned respectively among the four series elements 15, and the four parallel elements 17 connecting the four ports 19 to the reference potential section (e.g., the GND terminal 49G). The first parallel element (i.e., any one of the parallel elements 17) of the four parallel elements 17 may include an in-chip element (the entire first parallel element in the embodiment) included in the chip 5.

In this case, for example, as will be described later, providing a part of the hybrid unit 11 in the chip 5 is simplified. The four series elements 15 electrically constitute the loop 13, whereas the four parallel elements 17 electrically and independently branch off from the loop 13, so that when the part of the hybrid unit 11 is to be structurally separated, the configuration where the parallel elements 17 are separated is likely to be simpler in structure than the configuration where the series elements 15 are separated.

The in-chip element included in the first parallel element (i.e., any one of the parallel elements 17) of the four parallel elements 17 may include a first capacitor (i.e., capacitor C (any one of C1 to C4) as the entire first parallel element in the embodiment).

In this case, for example, the hybrid unit 11 including the four inductors L and the four capacitors C illustrated in FIG. 3 and the like can be used. For example, as mentioned above, the advantage where the piezoelectric body 31b of the chip 5 having a higher dielectric constant than the multilayer substrate 3 can be used is exhibited.

The first filter 9 may include an acoustic wave filter (i.e., the entire first filter 9 is an acoustic wave filter in the embodiment). The chip 5 may include the piezoelectric body 31b and an excitation electrode (IDT electrode 33). The IDT electrode 33 may be located on the piezoelectric body 31b to constitute an acoustic wave filter. The first capacitor (i.e., capacitor C provided in the chip 5) may be located on the piezoelectric body 31b.

In this case, for example, as mentioned above, the piezoelectric body 31b of the chip 5 having a higher dielectric constant than the multilayer substrate 3 can be used as a capacitor C. Because the piezoelectric body 31b already exists for an acoustic wave filter, the probability of a size increase in the filter device 1 as a result of using a piezoelectric body as a capacitor C is reduced.

In the configuration where the first filter 9 includes the acoustic wave filter, a first port (e.g., any one of the ports 19B to 19D of the first hybrid unit 11A in FIG. 6) included in the four ports 19 and connected to the first parallel element (i.e., the parallel element 17 having the in-chip element provided in the chip 5) may be connected to the aforementioned acoustic wave filter without the intervention of another filter and another hybrid coupler.

In this case, for example, the first port connected to the in-chip element is a port expected to be connected to the terminal 49 (i.e., the input terminal 49I or the output terminal 49O) of the chip 5 including the acoustic wave filter. Therefore, the in-chip element is connected to the first port by being connected to the terminal 49 connected to the first port. Specifically, unlike a case where the first port is connected to one of the external terminals 7 (e.g., the port 19A of the first hybrid unit 11A in FIG. 6), a dedicated terminal 49 (i.e., a new terminal 49 different from the terminal 49 for the acoustic wave filter) for connecting the first port and the in-chip element to each other does not need to be provided.

The first filter 9 (acoustic wave filter) may include the multiple series resonators 29S and the multiple parallel resonators 29P. The multiple series resonators 29S may be series-connected to each other. The multiple parallel resonators 29P may be parallel-connected to each other between the series arm 51 including the multiple series resonators 29S and the reference potential section (GND terminal 49G). The first port (i.e., any one of the ports 19) of the hybrid unit 11 connected to the first capacitor (i.e., the capacitor C located in the chip 5) may be connected to one end of the series arm 51. The multiple parallel resonators 29P may include a first parallel resonator (parallel resonator 29P) connected to the first port side relative to the series resonator 29S located electrically closest toward the first port. The first parallel resonator may be shared with at least a part (e.g., the capacitor C2b in FIG. 5) of the first capacitor.

In this case, for example, the parallel resonator 29P is shared with the capacitor C, so that the filter device 1 can be reduced in size.

In addition to the capacitor shared with the parallel resonator 29P, the first capacitor (e.g., the capacitor C2 in FIG. 5) may include a second capacitor (e.g., the capacitor C2a in FIG. 5) included in the chip 5 and not shared with the parallel resonator 29P of the acoustic wave filter.

In this case, for example, as mentioned above, size reduction can be achieved as a result of the parallel resonator 29P being shared with a part (capacitor C2b) of the capacitor C, while the capacitance of the capacitor C can be readily adjusted by the capacitor C2a.

The first port (e.g., the port 19A of the first hybrid unit 11A in FIG. 6) included in the four ports 19 and connected to the first parallel element may be connected to one of the external terminals 7 (e.g., the antenna terminal 7A in FIG. 6) of the filter device 1 without the intervention of the first filter 9 and another filter.

In other words, the parallel element 17 directly connected to the external terminal may partially be provided in the chip 5. In this case, as compared with a configuration where the parallel element 17 is provided outside (e.g., the circuit board (not illustrated) on which the filter device 1 is mounted), the hybrid unit 11 is completely contained in the filter device 1, thereby achieving improved ease of handling.

The four parallel elements 17 may be the four capacitors C1 to C4 having the same capacitance.

In this case, for example, the hybrid unit 11 including the four inductors L1 to L4 and the four capacitors C1 to C4, as illustrated in FIG. 3, can be used. Since the capacitances of the capacitors C1 to C4 can be uniformly adjusted, the adjustment of the operating frequency of the hybrid unit 11 is simplified.

As illustrated in FIG. 6, the filter device 1 may include a first 90° hybrid coupler (first hybrid unit 11A), a second 90° hybrid coupler (second hybrid unit 11B), a first filter system (transmission filter system 12), and a second filter system (reception filter system 14). The first 90° hybrid coupler may be connected to a common terminal (antenna terminal 7A). The second 90° hybrid coupler may be connected to a first terminal (transmission terminal 7T). The first filter system may be connected to the common terminal via the first 90° hybrid coupler and be connected to the first terminal via the second 90° hybrid coupler, and may allow a signal in a first passband (transmission band) to pass through the first filter system. The second filter system may be connected to the common terminal via the first 90° hybrid coupler and be connected to a second terminal (reception terminal 7R), and may allow a signal in a second passband (reception band) different from the first passband to pass through the second filter system. The transmission filter system 12 may include a second filter and a third filter (transmission filters 9TA and 9TB) that allow a signal in the first passband to pass therethrough. The second filter and the third filter may be connected to the first 90° hybrid coupler and the second 90° hybrid coupler to have a connection relationship in which, when a signal is input to one of the common terminal and the first terminal, signals phase-shifted by 90° from each other are distributed to the second filter and the third filter, and the distributed signals are turned into signals with the same phase and are output to the other one of the common terminal and the first terminal. The first 90° hybrid coupler or the second 90° hybrid coupler may be a first hybrid coupler (i.e., the hybrid unit 11 partially provided in the chip 5). The second filter, the third filter, or the second filter system may include the first filter 9 (i.e., a filter included in the chip 5 provided with a part of the hybrid unit 11). Specifically, at least one selected from the group consisting of the second filter, the third filter, and the second filter system may at least partially be provided in the chip 5 provided with the part of the hybrid unit 11.

In the above-described configuration, for example, as mentioned above, nonlinear distortion can be reduced in the process of distributing, combining, and the like of signals.

From a different viewpoint from the above, the multilayer substrate 3 may include a first surface (upper surface), the pads 25, and a first circuit (e.g., the loop 13). The pads 25 are located on the upper surface of the multilayer substrate 3, and the chip 5 is mountable on the pads 25. The first circuit may include the first hybrid coupler (hybrid unit 11). The first circuit may include the four inductors L series-connected to one another and electrically constituting the loop 13, and the four ports 19 electrically positioned respectively among the inductors L. The first port (e.g., the port 19B in FIG. 3) of the four ports 19 may be connected to the pads 25. When the chip 5 is not mounted on the pads 25, the first port and the reference potential section (e.g., a terminal included in the external terminals 7 and supplied with the reference potential and the pads 25 supplying the reference potential to the chip 5) may be unconnected. In other words, when the chip 5 is mounted, the first port may be connected to the reference potential section via the parallel element 17 of the chip 5.

Such a multilayer substrate 3 can be used in the filter device 1 in which the hybrid unit 11 is configured by mounting the aforementioned chip 5 on the multilayer substrate 3. The multilayer substrate 3 may be distributed without the chip 5 mounted thereon.

From another different viewpoint, the communication apparatus 151 may include the filter device 1, the antenna 159 connected to the filter device 1, and the integrated circuit element (RF-IC 153) connected to the antenna 159 via the filter device 1.

As mentioned above, for example, because the filter device 1 can enhance productivity, the productivity of the communication apparatus 151 including the filter device 1 can also be enhanced accordingly.

In the above embodiment, each of the hybrid unit 11, the first hybrid unit 11A, and the second hybrid unit 11B is an example of a first hybrid coupler. Each of the first filter 9, the transmission filters 9TA and 9TB, and the reception filter 9R is an example of a first filter, as well as an example of an acoustic wave filter. Each of the capacitors C1 to C4 is an example of a first parallel element, an example of an in-chip element, and an example of a first capacitor. The GND terminal 49G is an example of a reference potential section. The IDT electrode 33 is an example of an excitation electrode. Each of the ports 19A to 19D is an example of a first port. The capacitor C2b in FIG. 3 is an example of a second capacitor not shared with a parallel resonator. The antenna terminal 7A is an example of a common terminal. The transmission terminal 7T is an example of a first terminal. The first hybrid unit 11A is an example of a first 90° hybrid coupler. The second hybrid unit 11B is an example of a second 90° hybrid coupler. The transmission filter system 12 is an example of a first filter system. The reception filter system 14 is an example of a second filter system. The transmission filters 9TA and 9TB are examples of a second filter and a third filter. The loop 13 is an example of a first circuit. The RF-IC 153 is an example of an integrated circuit element.

The technology according to the present disclosure is not limited to the above embodiment and may be implemented in various configurations.

For the sake of convenience, the description of the embodiment indicates the advantage (i.e., the advantage of enhanced productivity) where the operating frequency of the hybrid coupler can be adjusted mainly by a part of the hybrid coupler provided in the chip, and the multilayer substrate can be used commonly among various chips. Alternatively, the technology according to the present disclosure does not need to be implemented in the configuration where such an advantage is exhibited. Even in such a case, for example, an advantage, such as an ability to use a piezoelectric body of a chip having a high dielectric constant as a capacitor of a hybrid coupler, is exhibited.

The filter device is not limited to a duplexer. For example, the filter device may include, as the first filter system and the second filter system, two reception paths with different passbands or two transmission paths with different passbands. The filter device may include another filter system in addition to the first filter system and the second filter system. For example, the filter device may be a triplexer including three filter systems, or may be a quadplexer including four filter systems. The filter device may include a single first filter alone (i.e., may be a filter).

Each hybrid coupler is not limited to a 90° hybrid coupler, and may be a 180° hybrid coupler. A filter device having a combination of a 180° hybrid coupler and a filter is described in, for example, Patent Literature 2.

### REFERENCE SIGNS

1 filter device
3 multilayer substrate
5 chip
9 first filter
11 hybrid unit (first hybrid coupler)

1. A filter device comprising:
a multilayer substrate;
a chip mounted on the multilayer substrate;
a first filter at least partially included in the chip; and
a first hybrid coupler a part of which is included in the multilayer substrate and another part of which is included in the chip, the first hybrid coupler being connected to the first filter.

2. The filter device according to claim 1,
wherein the first hybrid coupler comprises:
four series elements series-connected to one another and electrically comprising a loop;
four ports electrically positioned respectively among the four series elements; and
four parallel elements connecting the four ports to a reference potential section, and
wherein a first parallel element of the four parallel elements comprises an in-chip element included in the chip.

3. The filter device according to claim 2,
wherein the in-chip element comprises a first capacitor.

4. The filter device according to claim 3,
wherein the first filter comprises an acoustic wave filter,
wherein the chip comprises:
a piezoelectric body; and
an excitation electrode of the acoustic wave filter, the excitation electrode being located on the piezoelectric body, and
wherein the first capacitor is located on the piezoelectric body.

5. The filter device according to claim 2,
wherein the first filter comprises an acoustic wave filter, and
wherein a first port included in the four ports and connected to the first parallel element and the acoustic wave filter are connected to each other without intervention of another filter and another hybrid coupler.

6. The filter device according to claim 3,
wherein the first filter comprises an acoustic wave filter,
wherein a first port included in the four ports and connected to the first parallel element and the acoustic wave filter are connected to each other without intervention of another filter and another hybrid coupler,
wherein the acoustic wave filter comprises:
a plurality of series resonators series-connected to each other; and
a plurality of parallel resonators parallel-connected to each other between a series arm and the reference potential section, the series arm comprising the plurality of series resonators,
wherein the first port and one end of the series arm are connected to each other,
wherein the plurality of parallel resonators comprises a first parallel resonator connected to a side of the first port relative to the series resonator located electrically closest toward the first port, and
wherein the first parallel resonator is shared with at least a part of the first capacitor.

7. The filter device according to claim 6,
wherein the first capacitor comprises a second capacitor included in the chip and not shared with the parallel resonators of the acoustic wave filter.

8. The filter device according to claim 2,
wherein a first port included in the four ports and connected to the first parallel element and an external terminal of the filter device are connected to each other without intervention of the first filter and another filter.

9. The filter device according to claim 2,
wherein the four parallel elements are four capacitors having capacitances identical to one another.

10. The filter device according to claim 1, further comprising:
a first 90° hybrid coupler connected to a common terminal;
a second 90° hybrid coupler connected to a first terminal;
a first filter system that is connected to the common terminal via the first 90° hybrid coupler, is connected to the first terminal via the second 90° hybrid coupler, and is configured to allow a signal in a first passband to pass through the first filter system; and
a second filter system that is connected to the common terminal via the first 90° hybrid coupler, is connected to a second terminal, and is configured to allow a signal in a second passband different from the first passband to pass through the second filter system,
wherein the first filter system comprises a second filter and a third filter each configured to allow the signal in the first passband to pass therethrough,
wherein the second filter and the third filter are connected to the first 90° hybrid coupler and the second 90° hybrid coupler to have a connection relationship in which, when a signal is input to one of the common terminal and the first terminal, signals phase-shifted by 90° from each other are distributed to the second filter and the third filter, and the distributed signals are turned into signals with identical phases and are output to an other one of the common terminal and the first terminal,
wherein the first 90° hybrid coupler or the second 90° hybrid coupler is the first hybrid coupler, and
wherein the second filter, the third filter, or the second filter system comprises the first filter.

11. A multilayer substrate comprising:
a first surface;
a pad that is located at the first surface and on which a chip is mountable; and
a first circuit comprising a first hybrid coupler,
wherein the first circuit comprises:
four inductors series-connected to one another and electrically comprising a loop; and
four ports electrically positioned respectively among the four inductors,
wherein a first port of the four ports is connected to the pad, and
wherein the first port and a reference potential section are unconnected when the chip is not mounted on the pad.

12. A communication apparatus comprising:
the filter device according to claim 1;
an antenna connected to the filter device; and
an integrated circuit element connected to the antenna via the filter device.
